(19) United States
(12) Patent Application Publication
(10) Pub. No.: US 2014/0159132 A1
(43) Pub. Date: Jun. 12, 2014

(54) MEMORY ARRAYS WITH AIR GAPS BETWEEN CONDUCTORS AND THE FORMATION THEREOF

(71) Applicant: MICRON TECHNOLOGY, INC., Boise, ID (US)

(72) Inventors: David A. Daycock, Boise, ID (US); Matthew J. King, Boise, ID (US); Christopher J. Larsen, Boise, ID (US)

(73) Assignee: MICRON TECHNOLOGY, INC., Boise, ID (US)

(21) Appl. No.: 13/706,532

(22) Filed: Dec. 6, 2012

(51) Int. Cl. H01L 29/51; H01L 29/40

(52) U.S. Cl. CPC H01L 29/515; H01L 29/401
USPC 257/314; 438/595

(57) ABSTRACT

Memory arrays and their formation are disclosed. The formation of one such memory array includes forming first and second spacers respectively adjacent to sidewalls of first and second conductors so that the first and second spacers extend into an opening between the first and second conductors and terminate above bottoms of the first and second conductors, and closing the opening with a material that extends between the first and second spacers so that an air gap is formed in the closed opening.

### FIELD

The present disclosure relates generally to memories, and in particular, in one or more embodiments, the present disclosure relates to memory arrays with air gaps between conductors and the formation thereof.

### BACKGROUND

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

Flash memory devices (e.g., NAND, NOR, etc.) have developed into a popular source of non-volatile memory for a wide range of electronic applications. Non-volatile memory is memory that can retain its data values for some extended period without the application of power. Flash memory devices typically use a one-transistor memory cell that allows for high memory densities, high reliability, and low power consumption. Changes in threshold voltage of the cells, through programming (which is sometimes referred to as writing) of charge-storage structures (e.g., floating gates or charge traps) or other physical phenomena (e.g., phase change or polarization), determine the data value of each cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

In a NOR flash architecture, a column of memory cells are coupled in parallel with each memory cell coupled to a data line, such as a bit line. A “column” refers to a group of memory cells that are commonly coupled to a local data line, such as a local bit line. It does not require any particular orientation or linear relationship, but instead refers to the logical relationship between memory cell and data line.

Typically, the array of memory cells for NAND flash memory devices is arranged such that the control gate of each memory cell of a row of the array is connected together to form an access line, such as a word line. Columns of the array include strings (often termed NAND strings) of memory cells connected together in series, source to drain, between a pair of select transistors, a source select transistor and a drain select transistor. Each source select transistor is connected to a source line, while each drain select transistor is connected to a data line, such as column bit line.

In order for memory manufacturers to remain competitive, memory designers are constantly trying to increase the density of memory devices. Increasing the density of a flash memory device generally involves reducing the spacing between memory cells. The reduced spacing can increase the capacitive coupling (e.g., termed parasitic capacitance) between adjacent memory cells, e.g., that may affect the threshold voltage, and thus the programmed data value, of the memory cell. For example, a capacitive coupling may exist between charge-storage structures of adjacent memory cells in adjacent rows and in adjacent columns of memory cells, between charge-storage structures and control gates of adjacent memory cells in adjacent rows and in adjacent columns of memory cells, and between adjacent data lines.

For the reasons stated above, and for other reasons stated below which will become apparent to those skilled in the art upon reading and understanding the present specification, there is a need in the art for alternative techniques for reducing the capacitive coupling between adjacent memory cells.

### BRIEF DESCRIPTION OF THE DRAWINGS

FIG. 1 is a simplified block diagram of a memory system, according to an embodiment.

FIG. 2 is a schematic of a NAND memory array, according to another embodiment.

FIGS. 3A-3F are cross-sectional views of a portion of a memory array during various stages of fabrication, according to another embodiment.

FIGS. 4A-4D are cross-sectional views during various stages of the formation of air gaps between adjacent structures, according to another embodiment.

### DETAILED DESCRIPTION

In the following detailed description, reference is made to the accompanying drawings that form a part hereof, and in which is shown, by way of illustration, specific embodiments. In the drawings, like numerals describe substantially similar components throughout the several views. Other embodiments may be utilized and structural, logical, and electrical changes may be made without departing from the scope of the present disclosure. The following detailed description is, therefore, not to be taken in a limiting sense.

The term semiconductor can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps may have been utilized to form regions/junctions in the base semiconductor structure, and the term semiconductor can include the underlying layers containing such regions/junctions.

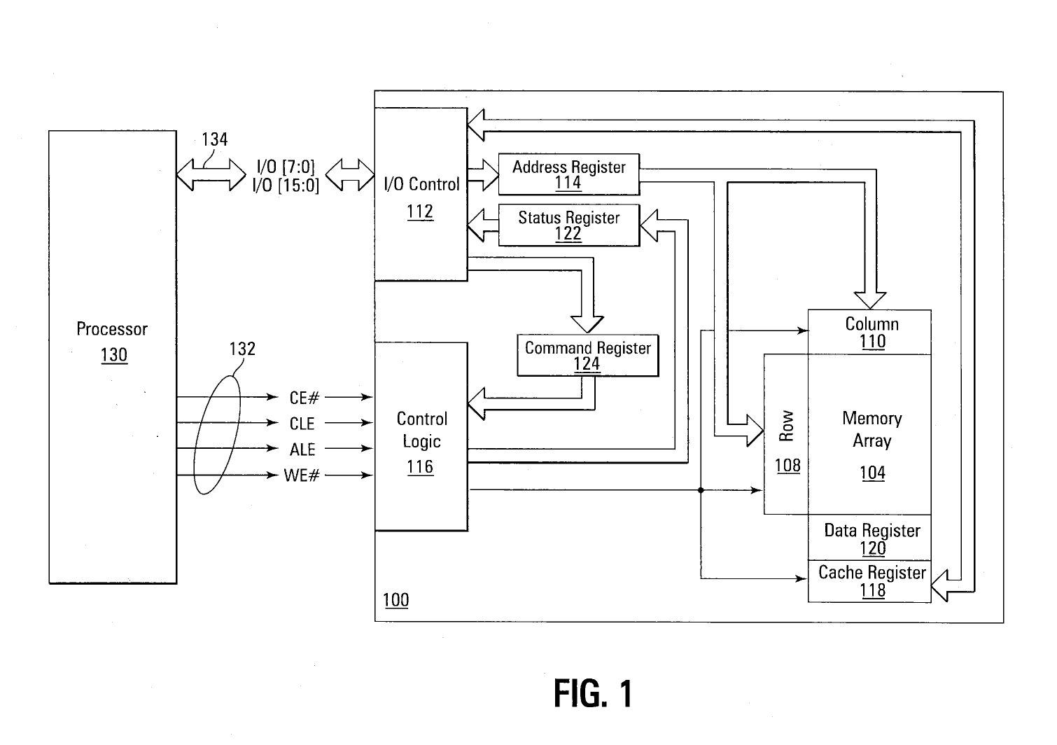

FIG. 1 is a simplified block diagram of an integrated circuit device, such as a NAND flash memory device 100, in communication with a processor 130 as part of an electronic system, according to an embodiment. The processor 130 may be a memory controller or other external host device.

Memory device 100 includes an array of memory cells 104 formed in accordance with embodiments of the disclosure. For example, memory array 104 might be formed by forming first and second spacers respectively adjacent to sidewalls of first and second conductors, such as first and second data lines (e.g., first and second bit lines) or first and second access lines (e.g., first and second word lines) so that the first and second spacers extend into an opening between the first and second conductors and terminate above bottoms of the first and second conductors, and by closing the opening with a material that extends between the first and second spacers so that an air gap is formed in the closed opening.

For some embodiments, the spacers can promote pinch off of the material that closes the opening so that the material can pinch off between the spacers, e.g., adjacent to the upper region of the opening. For example, this can reduce amount of the material (e.g., that might typically have a larger dielectric constant that air, for example) that might form on the sidewalls of the conductors, e.g., facilitating a larger air gap between the conductors. In some embodiments, the larger air gap might extend between charge-storage structures that might be under the conductors.

Although referred to herein as air gaps, it will be understood that the air gaps as defined herein may contain one or more gaseous components other than, or in addition to, ambient air. For example, an air gap as defined herein may contain oxygen, nitrogen, argon, neon or other gas compatible (e.g., inert) with the surrounding structures, such as conductors, data lines, access lines, memory cells, charge-storage structures, etc., or a gas containing a mixture of one or more such gaseous components. For one or more embodiments, the gas contained in an air gap of the present disclosure may further be below atmospheric pressure.

A row decoder 108 and a column decoder 110 are provided to decode address signals. Address signals are received and decoded to access memory array 104.

Memory device 100 also includes input/output (I/O) control circuitry 112 to manage input of commands, addresses, and data to the memory device 100 as well as output of data and status information from the memory device 100. An address register 114 is in communication with I/O control circuitry 112, and row decoder 108 and column decoder 110, to latch the address signals prior to decoding. A command register 124 is in communication with I/O control circuitry 112 and control logic 116 to latch incoming commands. Control logic 116 controls access to the memory array 104 in response to the commands and generates status information for the external processor 130. The control logic 116 is in communication with row decoder 108 and column decoder 110 to control the row decoder 108 and column decoder 110 in response to the addresses.

Control logic 116 is also in communication with a cache register 118. Cache register 118 latches data, either incoming or outgoing, as directed by control logic 116 to temporarily store data while the memory array 104 is busy writing or reading, respectively, other data. During a write operation, data is passed from the cache register 118 to data register 120 for transfer to the memory array 104; then new data is latched in the cache register 118 from the I/O control circuitry 112. During a read operation, data is passed from the cache register 118 to the I/O control circuitry 112 for output to the external processor 130; then new data is passed from the data register 120 to the cache register 118. A status register 122 is in communication with I/O control circuitry 112 and control logic 116 to latch the status information for output to the processor 130.

Memory device 100 receives control signals at control logic 116 from processor 130 over a control link 132. The control signals may include at least a chip enable CE#, a command latch enable CLE, an address latch enable ALE, and a write enable WE#. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands are received over input/output (I/O) pins [7:0] of I/O bus 134 at I/O control circuitry 112 and are written into command register 124. The addresses are received over input/output (I/O) pins [7:0] of bus 134 at I/O control circuitry 112 and are written into address register 114. The data are received over input/output (I/O) pins [7:0] for an 8-bit device or input/output (I/O) pins [15:0] for a 16-bit device at I/O control circuitry 112 and are written into cache register 118. The data are subsequently written into data register 120 for programming memory array 104. For another embodiment, cache register 118 may be omitted, and the data are written directly into data register 120. Data are also output over input/output (I/O) pins [7:0] for an 8-bit device or input/output (I/O) pins [15:0] for a 16-bit device.

It will be appreciated by those skilled in the art that additional circuitry and signals can be provided, and that the memory device of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins may be used in the various embodiments.

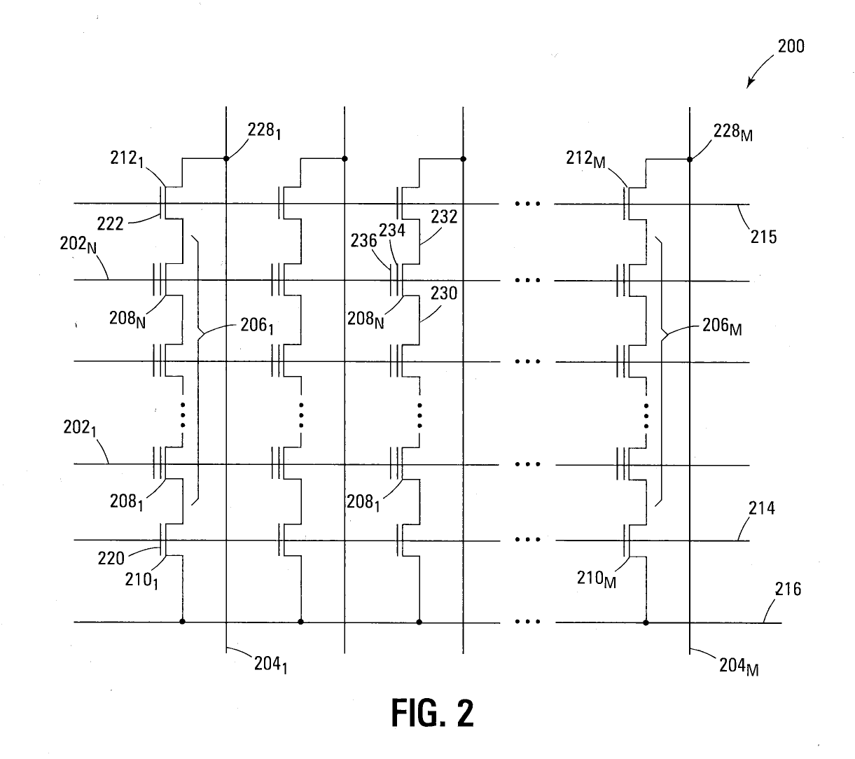

FIG. 2 is a schematic of a NAND memory array 200, e.g., as a portion of memory array 104, in accordance with another embodiment. Memory array 200 includes access lines, such as word lines 202₁ to 202_{N}, and data lines, such as bit lines 204₁ to 204_{M}. For ease of addressing in the digital environment, the number of word lines 202 and the number of bit lines 204 are each some power of two, e.g., 256 word lines 202 by 4,096 bit lines 204. The bit lines 204 may be coupled to global data lines, such as global bit lines (not shown), in a many-to-one relationship.

Memory array 200 is arranged in rows (each corresponding to a word line 202) and columns (each corresponding to a bit line 204). Each column may include a string, such as one of NAND strings 206₁ to 206_{M}. Each NAND string 206 is coupled to a common source line 216 and includes memory cells 208₁ to 208_{N}, each located at an intersection of a word line 202 and a bit line 204. The memory cells 208 represent non-volatile memory cells for storage of data. The memory cells 208 of each NAND string 206 are connected in series, source to drain, between a source select transistor 210 and a drain select transistor 212.

source select transistor 210 drain select transistor 212 source select transistor 210 drain select transistor 212A source of each source select transistor 210 is connected to common source line 216. The drain of each source select transistor 210 is connected to the source of the memory cell 208 of the corresponding NAND string 206. For example, the drain of source select transistor 210₁ is connected to the source of memory cell 208₁ of the corresponding NAND string 206₁. Therefore, each source select transistor 210 selectively couples a corresponding NAND string 206 to common source line 216. A control gate 220 of each source select transistor 210 is connected to a source select line 214.

The drain of each drain select transistor 212 is connected to the bit line 204 for the corresponding NAND string at a drain contact 228. For example, the drain of drain select transistor 212₁ is connected to the bit line 204₁ for the corresponding NAND string 206₁ at drain contact 228₁. The source of each drain select transistor 212 is connected to the drain of the last memory cell 208_{N} of the corresponding NAND string 206. For example, the source of drain select transistor 212₁ is connected to the drain of memory cell 208_{N} of the corresponding NAND string 206₁. Therefore, each drain select transistor 212 selectively couples a corresponding NAND string 206 to a corresponding bit line 204. A control gate 222 of each drain select transistor 212 is connected to a drain select line 215.

Typical construction of planar memory cells 208 includes a source 230 and a drain 232, a charge-storage structure 234 (e.g., a floating gate, charge trap, etc.) that can store a charge that determines a data value of the cell, and a control gate 236, as shown in FIG. 2. Memory cells 208 have their control gates 236 coupled to (and in some cases from) a word line 202. A column of the memory cells 208 is a NAND string 206 coupled to a given bit line 204. A row of the memory cells 208 are those memory cells commonly coupled to a given word line 202.

Although the examples of FIGS. 1 and 2 were discussed in conjunction with NAND flash, the embodiments described herein are not limited to NAND flash, but can include other flash architectures, such as NOR flash, etc.

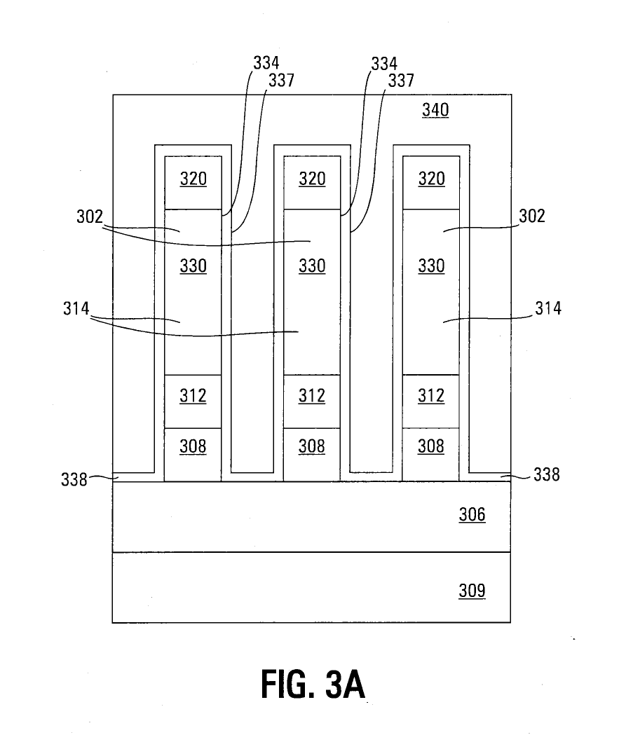

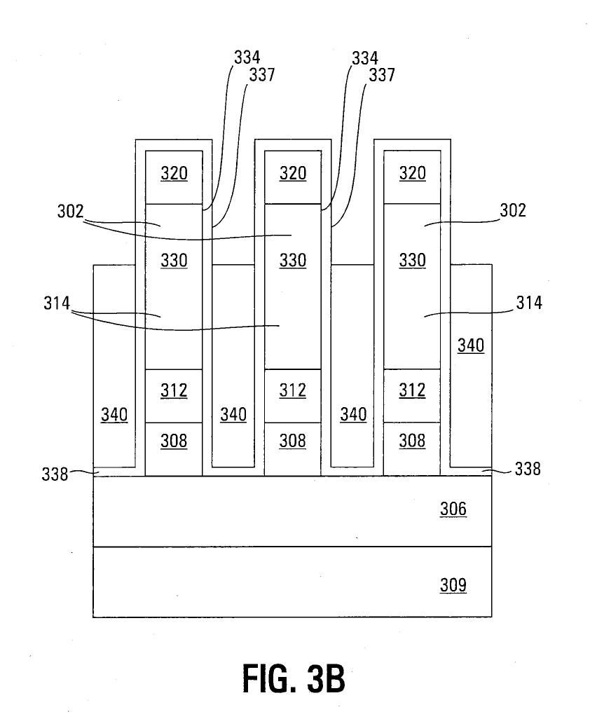

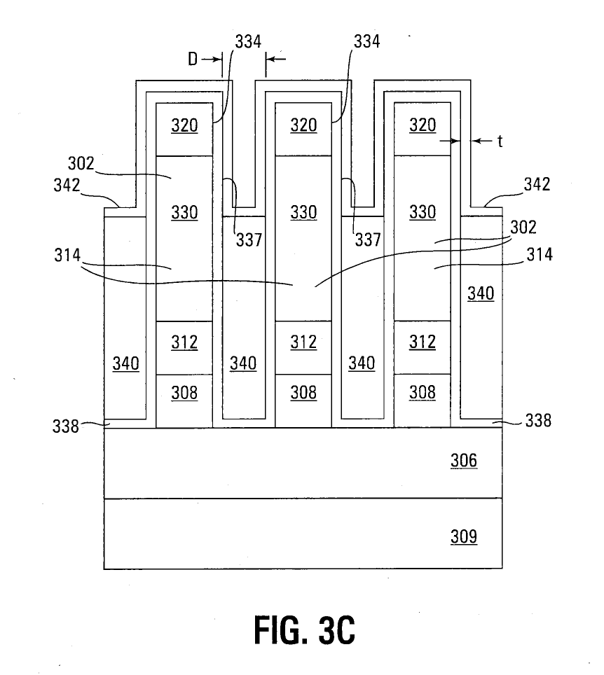

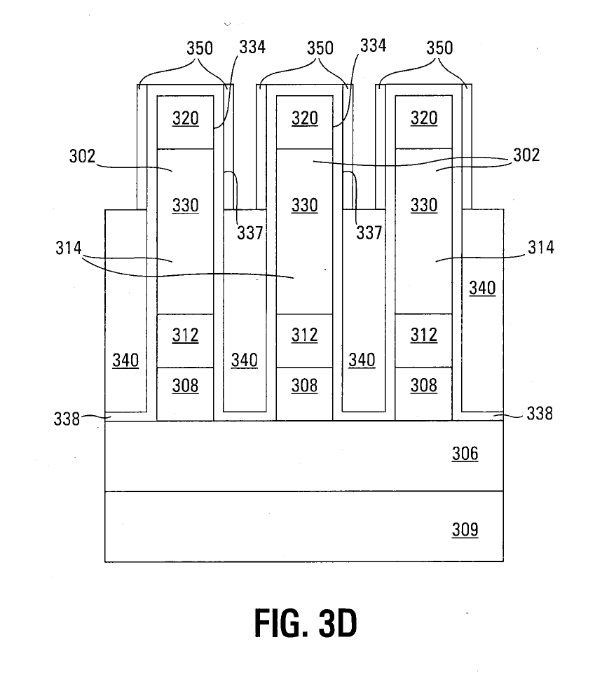

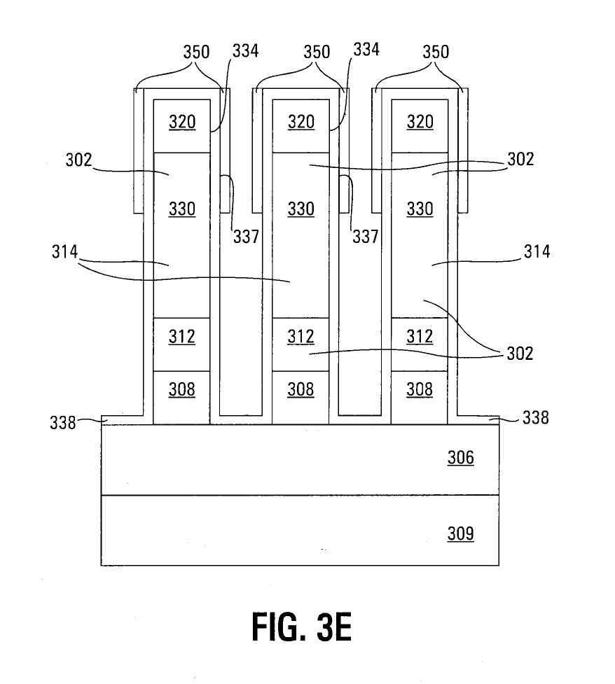

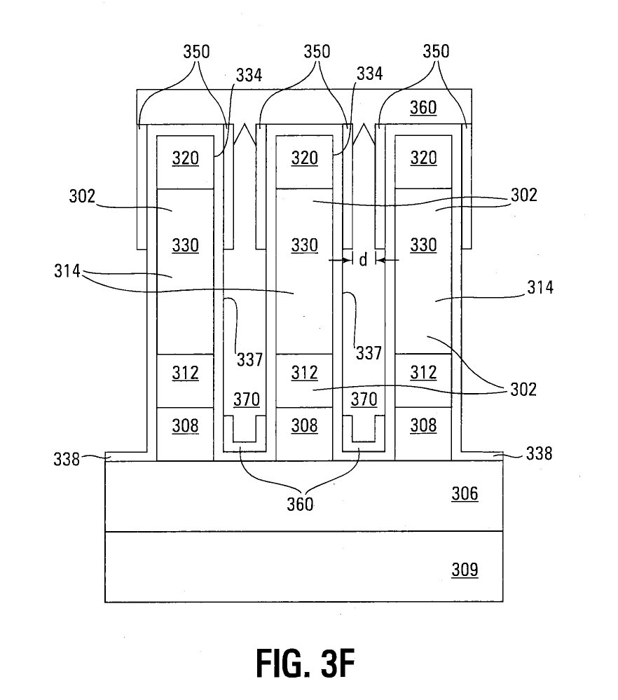

FIGS. 3A-3F are cross-sectional views of a portion of a memory array, such as a portion of memory array 104 of memory device 100 in FIG. 1 or a portion of memory array 200 in FIG. 2, during various stages of fabrication, e.g., during the formation of air gaps between adjacent structures, such as adjacent memory cells. For some embodiments, the array portion may include memory cells 302. The cross-sectional views of the array portion in FIGS. 3A-3F are along a data-line (e.g., bit-line) direction, such as a column direction. For example, a memory cell 302 might form a portion of a row of memory cells that might extend, e.g., substantially perpendicularly, into and out of the face planes of FIGS. 3A-3F. As such, the adjacent memory cells 302 might respectively represent portions of adjacent rows of memory cells. For example, the memory cells 302 along the column direction in FIGS. 3A-3F might form a portion of a column of memory cells, such as a portion of a string of series-coupled memory cells (e.g., a NAND string).

In FIG. 3A, the fabrication of the memory cells 302 may be substantially complete for some embodiments. For some embodiments, each memory cell 302 may include a charge-storage structure 308 that may be formed over dielectric 306 that may be formed over a semiconductor 309. Semiconductor 309 may be comprised of silicon, e.g., monocrystalline silicon, that may be conductively doped to have p-type conductivity, e.g., to form a p-well, or n-type conductivity, e.g., to form an n-well. Dielectric 306 may generally be formed of one or more dielectric materials, such as from an oxide, e.g., silicon oxide, an oxynitride, e.g., silicon oxynitride, etc.

Charge-storage structure 308 may generally be formed of one or more materials capable of storing a charge. Charge-storage structure 308 may be a floating gate formed from a conductor. The conductor may comprise, consist of, or consist essentially of conductively doped polysilicon and/or may comprise, consist of, or consist essentially of metal, such as a refractory metal, or a metal-containing material, such as a refractory metal silicide, or a metal nitride, e.g., a refractory metal nitride, as well as any other conductive material. The metals of chromium (Cr), cobalt (Co), hafnium (Hf), molybdenum (Mo), niobium (Nb), tantalum (Ta), titanium (Ti), tungsten (W), vanadium(V) and zirconium (Zr) are generally recognized as refractory metals.

For other embodiments, charge-storage structure 308 may be a charge trap. For example, the charge trap may be a dielectric, e.g., a high-dielectric-constant (high-K) dielectric, such as alumina (Al₂O₃) having a K of about 10, with embedded conductive particles (e.g., nano-dots), such as embedded metal particles or embedded nano-crystals (e.g., silicon, germanium, or metal crystals), a silicon-rich dielectric, or SiON/Si₃N₄. Other charge-storage structures are also known.

Each memory cell 302 may further include a dielectric 312, such as a blocking dielectric, over charge-storage structure 308 and a conductor 314 over dielectric 312. Dielectric 312 may be generally formed of one or more dielectric materials. For some embodiments, dielectric 312 may be a high-dielectric-constant (high-K) dielectric, such as alumina, hafnia (HfO₂), or zirconia (ZrO₂) with a K of about 20, or praeseodymium oxide (Pr₂O₃) with a K of about 30. Alternatively, dielectric 312 may be an oxide. For some embodiments, dielectric 312 might include an oxide-nitride-oxide (e.g., and ONO) structure.

Conductor 314 may generally be formed of one or more conductive materials. For example, conductor 314 may comprise, consist of, or consist essentially of conductively doped polysilicon and/or may comprise, consist of, or consist essentially of metal, such as a refractory metal, or a metal-containing material, such as a refractory metal silicide or a metal nitride, e.g., a refractory metal nitride, as well as any other conductive material.

A protective material 320, e.g., a dielectric, such as nitride, carbon, etc., may be formed over conductor 314, e.g., for protecting conductor 314, dielectric 312 and charge-storage structure 308 during the subsequent processing described below.

Dielectric 306 might be a tunnel dielectric for memory cells 302. Conductor 314 might form a control gate of each memory cell 302. For example, the control gates of memory cells 302 might form a portion of or might be coupled to access lines, such as word lines 330. For example, conductor 314 might form word lines 330.

Openings 334 may be formed between adjacent memory cells 302. For example, openings 334 may pass through protective material 320, conductor 314, dielectric 312, and charge storage structure 308, and may stop at or in dielectric 306 or semiconductor 309. For example, openings 334 might be formed by patterning and etching, e.g., through exposed portions of protective material 320, conductor 314, dielectric 312, and charge storage structure 308. For other embodiments, openings 334 might pass completely through dielectric 306 and might stop at or in semiconductor 309.

A protective material 338, e.g., a protective liner, such as a dielectric liner, might be formed in openings 334, e.g., to respectively form openings 337. Note that openings 337 may be openings 334 lined with protective material 338. For example, protective material 338 might be formed on sidewalls of memory cells 302. For example, protective material 338 might be formed on sidewalls of protective material 320, conductor 314, dielectric 312, and charge storage structure 308 of memory cells 302. Protective material 338 might be a conformal material for some embodiments.

Generally, protective material 338 may comprise, consist of, or consist essentially of one or more thicknesses of protective material, such as a thickness of oxide, e.g., silicon dioxide, and/or a thickness of nitride, such as silicon nitride, high-density plasma oxide, etc. Protective material 338 may be one or more thicknesses of protective material formed by a high-aspect-ratio process (HARP). For example, protective material 338 may include an oxide and/or nitride formed by the HARP.

A sacrificial material 340 may be formed over protective material 338, e.g., using a chemical vapor deposition (CVD) process, a spin-on process, etc. Sacrificial material 340 may generally be formed of resist (e.g., a multi-layer resist), amorphous carbon, transparent carbon, polysilicon, spin-on-dielectric, etc. For example, sacrificial material 340 may over fill openings 337.

A portion of sacrificial material 340 may be removed in FIG. 3B, e.g., by etching (e.g., using a dry-plasma etch). For example, sacrificial material 340 may be removed until a portion of the upper surface of sacrificial material 340 is at a certain distance above the bottoms of conductors 314, and thus of upper surfaces of the charge-storage structures 308 of memory cells 302, e.g., until sacrificial material 340 partially fills openings 337 to the certain distance above the bottoms of conductors 314. For some embodiments, the structure of sacrificial material 340 in FIG. 3B might be formed directly, e.g., using a spin-on process, thereby avoiding the need to form the structure of sacrificial material 340 in FIG. 3A and the subsequent removal process that removes the portion of sacrificial material 340 to form the structure of sacrificial material 340 in FIG. 3B.

A dielectric 342, e.g., a conformal dielectric, might be formed over sacrificial material 340 and over protective material 338 in FIG. 3C, e.g., using CVD or a diffusion-type process. For example, dielectric 342 might line the openings 337. Dielectric 342 may generally be formed of one or more dielectric materials. For example, dielectric 342 may be an oxide, nitride, or a nitride oxide formed by the HARP, an oxide formed by atomic layer deposition (ALD), a nitride formed by ALD, or tetraethylorthosilicate (TEOS). For some embodiments, dielectric 342 might be formed to have a thickness t that might be less than one half (½) the distance (e.g., spacing) D between adjacent memory cells 302 with protective material 338 thereover. For example, the distance D might be the width of the openings 337.

Subsequently, portions of dielectric 342 are selectively (e.g., anisotropically) removed, e.g., by an anisotropic etch, such as an anisotropic dry etch in FIG. 3D. For example, substantially horizontal portions of dielectric 342 over substantially horizontal surfaces of sacrificial material 340 and protective material 338 are selectively removed, leaving substantially vertical portions of dielectric 342 over (e.g., adjacent to) sidewalls of protective material 338, and thus the sidewalls of openings 337. The substantially vertical portions of dielectric 342 left over the sidewalls of protective material 338 may form separate, such as non-contiguous (e.g., independent), spacers 350 of dielectric 342 over (e.g., adjacent to) sidewalls of protective material 338.

Spacers 350 may extend into the openings 337 to the upper surface of sacrificial material 340. For example, spacers 350 may be over (e.g., adjacent to) sidewalls of openings 337.

The portions of dielectric 342 may be selectively removed until sacrificial material 340 is exposed and can thus be removed by a subsequent removal process. Sacrificial material 340 is subsequently removed, e.g. from openings 337, leaving spacers 350 and protective material 338, as shown in FIG. 3E. For example, sacrificial material 340 may be removed by an isotropic etch that is selective to sacrificial material 340. For example, sacrificial material 340 may be removed by an isotropic wet etch, an isotropic dry plasma etch, a dry-strip plasma clean, etc. For some embodiments, sacrificial material 340 may be completely removed from openings 337.

Note that an opening 337 may between successively adjacent structures, where each of the successively adjacent structures may include protective material 338 formed over (e.g., adjacent to) a sidewall of protective material 320, a sidewall of a conductor 314, a sidewall of a dielectric 312, and a sidewall of a charge-storage structure 308. For example, each of the successively adjacent structures may include at least a portion of a memory cell 302.

For example, each spacer 350 may be over (e.g., adjacent to) each of the successively adjacent structures and may extend only part way into the opening 337, e.g., terminating above a bottom of conductor 314, as shown in FIG. 3E. Note that conductor 314 may form a control gate of a memory cell 302, where the control gate may form a portion of or may be coupled to a word line 330. This means that each spacer 350 may terminate within a corresponding opening 337 above the bottom of the corresponding opening 337 and above the bottom of the control gate of a memory cell 302, and thus a word line 330.

For some embodiments, certain sacrificial-material-340-spacer-350-material pairings might be used to facilitate removing sacrificial material 340 selective to spacers 350. For example, photoresist sacrificial material 340 might be paired with ALD oxide spacers 350, ALD oxide sacrificial material 340 with HARP oxide spacers 350, spin-on-dielectric sacrificial material 340 with HARP oxide spacers 350, spin-on-dielectric sacrificial material 340 with furnace ALD oxide spacers 350, etc.

A material (e.g., a substantially non-conformal material) 360, e.g., a dielectric, having a low conformability, such as plasma-enhanced TEOS or silane oxide may then be formed over protective material 338 and portions of spacers 350, as shown in FIG. 3F. The distance d between adjacent spacers 350 may be such that material 360 pinches off adjacent to a top of each of openings 337, and thus the tops of spacers 350. A space between adjacent spacers 350 may have a relatively high aspect (height-to-width) ratio that may act to promote pinching off of material 360 adjacent to the tops of openings 337. For example, the presence of spacers 350 acts to constrict openings 337 adjacent to their tops. For some embodiments, spacers 350 form a constricted passage in openings 337.

Material 360 may extend between spacers 350 and may pinch off before openings 337 can be completely filled with material 360. For example, material 360 may pinch off before it reaches bottom ends of spacers 350. Material 360 thus closes openings 337 adjacent to the tops of openings 337. For example, material 360 may close the entrances to openings 337.

For some embodiments, some material 360 may form in openings 337, e.g., adjacent to charge-storage structures 308, before pinching off. For example, material 360 may cover the bottoms of openings 337 and the sidewalls of openings 337 adjacent to charge-storage structures 308. However, by causing material 360 to pinch off sooner, the presence of spacers 350 and the relatively high-aspect-ratio spaces therebetween act to reduce (e.g., limit) the amount of material 360 that might form on the sidewalls of openings 337 adjacent to charge-storage structures 308 compared to that which could form in the absence of spacers 350.

The closed (e.g., pinched-off) openings 337 form air gaps 370 within openings 337. Air gaps 370 may be between adjacent word lines 330 and between adjacent charge-storage structures 308. For example, air gaps 370 may be between the word lines 330 and between the charge-storage structures 308 of successively adjacent memory cells 302. For example, air gaps 370 may be between memory cells of successively adjacent rows of memory cells.

For some embodiments, air gaps 370 may extend substantially in a direction (e.g., in the direction) of the rows of memory cells 302, e.g., substantially in a direction into and out of the face plane of FIG. 3F that might be substantially perpendicular to the face plane of FIG. 3F.

For some embodiments, air gaps 370 might extend between opposing surfaces of protective material 338. For example, an air gap 370 might be in direct contact with the opposing surfaces of protective material 338.

Note that the spacers 350 within a single opening 337, e.g., adjacent to opposing sidewalls of the single opening 337, might not be connected to each other at their bottom ends. For example, the bottom ends of the spacers 350 within a single opening 337 might be separated from each other, as shown in FIG. 3F.

Causing material 360 to pinch off sooner, as a result of spacers 350, facilitates larger, e.g., wider, air gaps between adjacent word lines 330 and between adjacent charge-storage structures 308, and thus between memory cells 302 (e.g., between adjacent rows of memory cells 302), than might otherwise occur in the absence of spacers 350. Moreover, limiting spacers 350 to the upper regions of protective material 338, e.g., the upper regions of openings 337, and thus the upper regions of memory cells 302, facilitates larger, e.g., wider, air gaps between adjacent word lines 330 and between adjacent charge-storage structures 308 than might otherwise occur if spacers 350 were allowed to extend to the bottoms protective material 338, e.g., the bottoms of openings 337. Note that each spacer 350 may terminate within a corresponding air gap 370 above the bottom of the control gate of a memory cell 302 and thus a word line 330.

Note that since the dielectric constant of air or of other gaseous components is relatively low (e.g., 1.00059 for dry atmospheric air), the presence of an air gap between the charge-storage structures and word lines of successively adjacent memory cells 302 reduces the capacitive coupling, and thus the parasitic capacitance, between adjacent charge-storage structures and adjacent word lines. For example, the air gaps may reduce the capacitive coupling, and thus the parasitic capacitance, between charge-storage structures of adjacent memory cells in adjacent rows of memory cells and between charge-storage structures and control gates, e.g., word lines, of adjacent memory cells in adjacent rows of memory cells.

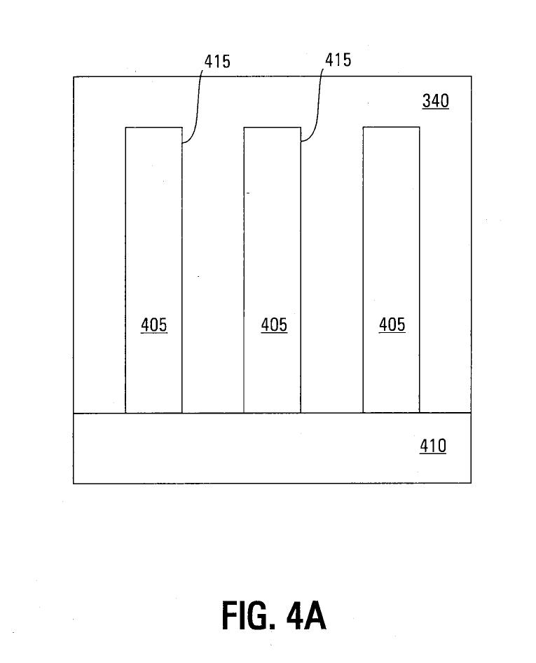

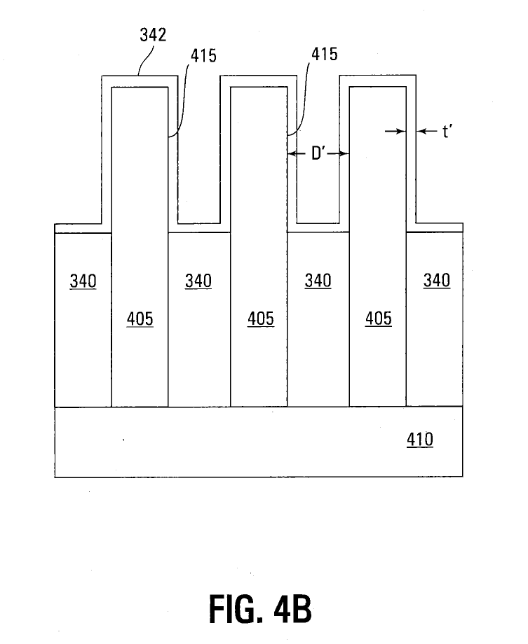

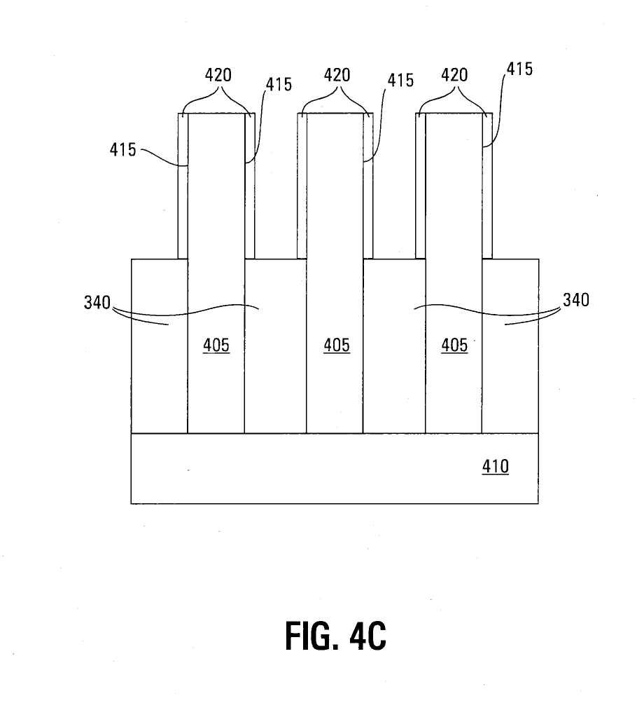

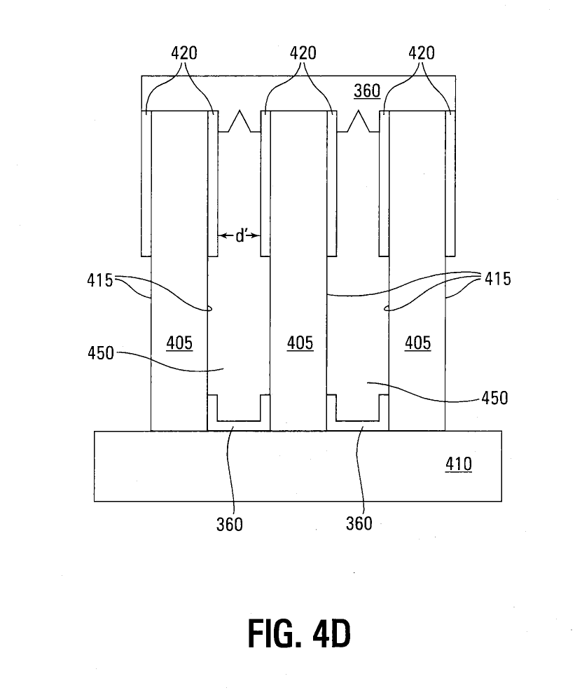

FIGS. 4A-4D are cross-sectional views, during various stages of the formation of air gaps between adjacent structures, for example, adjacent conductors, such as data lines, e.g., bit lines. In FIG. 4A, conductors 405, such as data lines (e.g., bit lines, such as bit lines 204 in FIG. 2), may be formed over a dielectric 410. For some embodiments, conductors 405 may be formed in memory array 104 of memory device 100 in FIG. 1. For other embodiments, dielectric 410 and conductors 405 might be formed over the structure of FIG. 3F, e.g., so that conductors 405 might be substantially perpendicular to the word lines 330 and substantially parallel to the face plane of FIG. 3F. For example, the cross-sectional views in FIGS. 4A-4D might be along an access-line (e.g., word-line) direction, such as a row direction in a memory array.

Dielectric 410 may generally be formed of one or more dielectric materials, such as from an oxide, e.g., silicon oxide, an oxynitride, e.g., silicon oxynitride, etc. Conductors 405 may generally be formed of one or more conductive materials. For example, conductor 405 may comprise, consist of, or consist essentially of conductively doped polysilicon and/or may comprise, consist of, or consist essentially of metal, such as a refractory metal, aluminum, copper, or a metal-containing material, such as a refractory metal silicide or a metal nitride, e.g., a refractory metal nitride, as well as any other conductive material.

Openings 415 have been formed between adjacent conductors 405, e.g., by patterning an etching, stopping at or within dielectric 410. The sacrificial material 340, e.g., described above in conjunction with FIG. 3B, may then be formed over conductors 405, e.g., using a chemical vapor deposition (CVD) process, a spin-on process, etc.

A portion of sacrificial material 340 may be removed, e.g., by etching (e.g., using a dry-plasma etch), until a portion of the upper surface of sacrificial material 340 is at a certain distance below the upper surfaces of conductors 405, as shown in FIG. 4B. For example, sacrificial material 340 may partially fill openings 415 to a certain distance above dielectric 410, and thus above the bottoms of conductors 405, after the removal. For some embodiments, the structure of sacrificial material 340 in FIG. 4B might be formed directly, e.g., using a spin-on process, thereby avoiding the need to form the structure of sacrificial material 340 in FIG. 4A and the subsequent removal process of a portion of sacrificial material 340 to form the structure of sacrificial material 340 in FIG. 4B.

Subsequently, the dielectric 342, e.g., a conformal dielectric, might be formed over sacrificial material 340 and conductors 405, as shown in FIG. 4B, e.g., in a manner similar to (e.g., the same manner as) that described above for dielectric 342 in conjunction with FIG. 3C. For example, dielectric 342 might line the openings 415.

For some embodiments, dielectric 342 might be formed to have a thickness t′ that might be less than one half (½) the distance (e.g., spacing) D′ between adjacent conductors 405. For example the distance D′ might be the width of the openings 415.

Subsequently, portions of dielectric 342 are selectively (e.g., anisotropically) removed in FIG. 4C, e.g., in a manner similar to (e.g., the same manner as) that described above in conjunction with FIG. 3D. For example, substantially horizontal portions of dielectric 342 over substantially horizontal surfaces of sacrificial material 340 and conductors 405 are selectively removed, leaving substantially vertical portions dielectric 342 over (e.g., adjacent to) sidewalls of conductors 405. The portions of dielectric 342 may be selectively removed until upper surfaces of sacrificial material 340 and upper surfaces of conductors 405 are exposed.

The substantially vertical portions of dielectric 342 left over the sidewalls of conductors 405 may form separate, such as non-contiguous (e.g., independent), spacers 420 of dielectric 342 over (e.g., adjacent to) sidewalls of conductors 405. For example, spacers 420 may extend into the openings 415 from the upper surfaces of conductors 405 to the upper surface of sacrificial material 340. For example, spacers 420 may be over (e.g., adjacent to) sidewalls of openings 415.

Sacrificial material 340 is subsequently removed, e.g. from openings 415, leaving spacers 420 and conductors 405, as shown in FIG. 4D. For example, sacrificial material 340 may be removed in a manner similar to (e.g., in the same manner as) that described above for sacrificial material 340 in conjunction with FIG. 3E. For example, sacrificial material 340 may be removed by an isotropic wet etch, an isotropic dry plasma etch, a dry-strip plasma clean, etc.

A distance d′ may be between the adjacent spacers 420. Note that spacers 420 may extend into a corresponding opening 415 and may terminate within the corresponding opening 415 above the bottom of the corresponding openings 415 and above the bottom of the conductors 405 on either side of the corresponding opening 415. For example, the presence of spacers 420 acts to constrict openings 415 adjacent to their tops. For some embodiments, spacers 420 form a constricted passage into openings 415.

The material 360 may then be formed over conductors 405, as shown in FIG. 4D, e.g., after the removal of sacrificial material 340. For example, material 360 may be formed in a manner similar to (e.g., in the same manner as) that described above for material 360 in conjunction with FIG. 3G.

The distance d′ between adjacent spacers 420 may be such that material 360 pinches off adjacent to a top of each of openings 415, and thus the tops of spacers 420 and the upper surfaces of conductors 405. For example, the space between adjacent spacers 420 may have a relatively high aspect (height-to-width) ratio that acts to promote pinching off of material 360 adjacent to the tops of openings 415. For example, material 360 may extend between adjacent spacers 420 and may pinch off before openings 415 can be completely filled with material 360. For example, material 360 may pinch off before it reaches bottom ends of spacers 420. Material 360 thus closes openings 415 adjacent to the tops of openings 415. For example, material 360 may close the entrances to openings 415.

For some embodiments, some material 360 may form in openings 415 before pinching off For example, material 360 may cover the bottoms of openings 415 and the sidewalls of openings 415 adjacent to the bottoms of openings 415. However, by causing material 360 to pinch off sooner, the presence of spacers 420 and the relatively high-aspect-ratios of the spaces therebetween act to reduce (e.g., limit) the amount of material 360 that might form on the sidewalls of openings 415 adjacent to the bottoms of openings 415 compared to that which could form in the absence of spacers 420.

The closed (e.g., pinched-off) openings 415 form air gaps 450 within openings 415. Air gaps 450 may be between adjacent to conductors 405. For example, air gaps 450 may extend substantially in a direction (e.g., in the direction) of conductors 405, and thus of columns of memory cells (e.g., that can be under conductors 405). For example, air gaps 450 might extend substantially in a direction into and out of the face plane of FIG. 4D that might be substantially perpendicular to the face plane of FIG. 4D. For some embodiments, an air gap 450 between adjacent conductors 405 might completely extend from one of those adjacent conductors 405 to the other.

Note that each of spacers 420 may terminate within a corresponding air gap 450 above the bottoms of the conductors 405 on either side of the corresponding air gap 450. Note that the spacers 420 within a single opening 415, e.g., adjacent to opposing sidewalls of the single opening 415, might not be connected to each other at their bottom ends. For example, the bottom ends of the spacers 420 within a single opening 415 might be separated from each other, as shown in FIG. 4D. Air gaps 450 act to reduce the capacitive coupling between adjacent conductors 405 and thus between memory cells that might be coupled to the adjacent conductors 405.

### CONCLUSION

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

1. A method of forming a memory array, comprising:
forming first and second spacers respectively adjacent to sidewalls of first and second control gates respectively of first and second memory cells so that the first and second spacers extend into an opening between the first and second control gates and terminate within the opening above bottoms of the first and second control gates; and
closing the opening with a material that extends between the first and second spacers so that an air gap is formed in the closed opening;
wherein the opening terminates at or within a dielectric without passing completely through the dielectric; and
wherein the dielectric acts as a tunnel dielectric for both the first and the second memory cells.

2. The method of claim 1, wherein forming the first and second spacers comprises forming the first and second spacers adjacent to a protective material adjacent to the sidewalls of the first and second control gates so that the protective material is between the first spacer and the sidewall of the first control gate and between the second spacer and the sidewall of the second control gate.

3. The method of claim 1, further comprising forming the first spacer adjacent to a sidewall of a protective material over an upper surface of the first control gate and forming the second spacer adjacent to a sidewall of a protective material over an upper surface of the second control gate.

4. The method of claim 1, wherein closing the opening with the material that extends between the first and second spacers comprises the material pinching off between the first and second spacers.

5. (canceled)

6. The method of claim 1, wherein the first and second control gates are respectively over first and second charge-storage structures respectively of the first and second memory cells and the opening is between the first and second charge-storage structures, and wherein the first and second spacers respectively terminate above upper surfaces of the first and second charge-storage structures.

7. The method of claim 1, wherein forming the first and second spacers comprises forming each of the first and second spacers to have a thickness that is less than ½ of a width of the opening.

8. The method of claim 1, wherein forming the first and second spacers comprises:
forming a sacrificial material in the opening so that the sacrificial material partially fills the opening above the bottoms of the first and second control gates to where the spacers will terminate;
forming a spacer material within the opening adjacent to the sidewalls of the first and second control gates and over the sacrificial material;
selectively removing a substantially horizontal portion of the spacer material over the sacrificial material to expose the sacrificial material and to form separate substantially vertical first and second portions of the spacer material that terminate at the sacrificial material above the bottoms of the conductors first and second control gates and that respectively correspond to the first and second spacers; and
removing the exposed sacrificial material from the opening.

9. The method of claim 8, wherein removing the exposed sacrificial material from the opening comprises completely removing the exposed sacrificial material from the opening.

10. The method of claim 1, wherein forming first and second spacers respectively adjacent to the sidewalls of first and second control gates comprises forming separate first and second spacers respectively adjacent to the sidewalls of first and second control gates.

11. A method of forming a memory array, comprising:
forming first and second memory cells;
forming an opening between the first and second memory cells that terminates at or within a dielectric without passing completely through the dielectric, wherein the dielectric acts as a tunnel dielectric for both the first and the second memory cells;
forming a sacrificial material within the opening so that an upper surface of the sacrificial material is at a level above bottoms of control gates of the first and second memory cells;
forming first and second spacers within the opening respectively adjacent to sidewalls of the first and second memory cells so that the first and second spacers are above the sacrificial material and so that the first and second spacers terminate at the upper surface of the sacrificial material;
removing the sacrificial material from the opening below where the first and second spacers terminate; and
after removing the sacrificial material from the opening, forming an other material over an entrance to the opening adjacent to the first and second spacers so that the other material closes the opening by pinching off between the first and second spacers;
wherein the closed opening forms an air gap between the first and second memory cells.

12. The method of claim 11, wherein forming the sacrificial material within the opening, comprises:
overfilling the opening with the sacrificial material; and
removing the sacrificial material so that the upper surface of the sacrificial material is at the level above the bottoms of the control gates of the first and second memory cells.

13. The method of claim 11, wherein forming the first and second spacers comprises:
lining the opening above the sacrificial material with a spacer material; and
selectively removing a substantially horizontal portion of the spacer material from the upper surface of the sacrificial material, leaving separate substantially vertical first and second portions of the spacer material respectively adjacent to sidewalls of the first and second memory cells and respectively corresponding to the first and second spacers.

14. The method of claim 11, further comprising lining the opening with a protective material before forming the sacrificial material within the opening, wherein forming the sacrificial material within the opening comprises forming the sacrificial material over the protective material, and wherein forming the first and second spacers comprises forming the spacers over the protective material.

15. The method of claim 11, further comprising forming a protective material over upper surfaces of the first and second memory cells before forming the opening, wherein forming the first and second spacers further comprises forming the first and second spacers respectively adjacent to sidewalls of the protective material over the upper surfaces of the first and second memory cells.

16. A method of forming a memory array, comprising:
forming first and second data lines;
forming a sacrificial material in an opening between the first and second data lines so that an upper surface of the sacrificial material is at a level above bottoms of the first and second data lines;
forming first and second spacers within the opening respectively adjacent to sidewalls of the first and second data lines so that the first and second spacers are above the sacrificial material and so that the spacers terminate at the upper surface of the sacrificial material;
removing the sacrificial material from the opening below where the spacers terminate; and
after removing the sacrificial material from the opening, forming an other material over an entrance to the opening adjacent to the first and second spacers so that the other material closes the opening by pinching off between the first and second spacers;
wherein the closed opening forms an air gap between the first and second data lines; and
wherein the closed opening does not extend below the bottoms of the data lines.

17. The method of claim 16, wherein forming the sacrificial material within the opening, comprises:
overfilling the opening with the sacrificial material; and
removing the sacrificial material so that the upper surface of the sacrificial material is at the level above the bottoms of the first and second data lines.

18. The method of claim 16, wherein forming the first and second spacers comprises:
lining the opening above the sacrificial material with a spacer material; and
selectively removing a substantially horizontal portion of the spacer material from the upper surface of the sacrificial material, leaving separate substantially vertical first and second portions of the spacer material respectively adjacent to sidewalls of the first and second data lines and respectively corresponding to the first and second spacers.

19-37. (canceled)
